(19) United States
(12) Patent Application Publication
(10) Pub. No.: US 2007/0099316 A1
(43) Pub. Date: May 3, 2007

(54) LED manufacturing process

(75) Inventors: Ming-Shun Lee, Taipei (TW); Ping-Ru Sung, Taipei (TW)

Correspondence Address: TROXELL LAW OFFICE PLLC, SUITE 1404, 5205 LEESBURG PIKE, FALLS CHURCH, VA, 22041, US

(73) Assignee: TAIWAN OASIS TECHNOLOGY CO., LTD.

(21) Appl. No.: 11/414,313

(22) Filed: May 1, 2006

(30) Foreign Application Priority Data
Oct. 28, 2005 (TW) 094137874

(51) Int. Cl. H01L 21/00

(52) U.S. Cl. 438/22; 257/E33.059

(57) ABSTRACT

An LED manufacturing process involves having a light emitting chip set in a preset loading pit on a carrier with an encapsulating material; conductive circuits with different electrodes being disposed of a substrate on the perimeter of the carrier; golden plated wire connecting the chip and the circuits; ;the carrier being them encapsulated using jet printing technique with a mixture of encapsulating material comprised of fluorescent powder and glue to achieve precise control of the range of jet printing for the encapsulating material to be consistently cover up in the carrier.

### BACKGROUND OF THE INVENTION

1. Field of the Invention

The present invention is related to a method for improving light emitting diode (LED) packaging efficiency, and more particularly, to a manufacturing process allowing consistent application of encapsulation material and upgrading production capacity.

2. Description of the Prior Art

As illustrated in FIG. 1 of the accompany drawings, an LED is essentially comprised of a light emitting chip f10 secured with an encapsulating material 40 in a carrier 20 provided with a pit 22; a golden plated wire 30 connects the light emitting chip 10 and two electrodes 21; and the chip 10 is then encapsulated with a encapsulating material 50 containing fluorescent material 51. Accordingly, when the chip 10 is conducted, a light source of the chip 10 excites the fluorescent powder 51 in the encapsulating material 50 to emit the light in expected color.

Usually, the encapsulating material 50 is applied by means of injection, extension and casting method. Wherein, the injection or extension method involves having the fluorescent material and glue mixed at a given ratio to be poured into a dedicated barrel, an injection machine and a X-Y movement mechanism are used to coat the encapsulating material by dot or by line upon the lighting emitting chip. However, either method prevents precise control of the containment of the fluorescent powder thus to fail the emission of the light in expected color and easy control of the encapsulating location resulting in deviation.

The casting method involves having the fluorescent powder and casting cake mixed a given ratio; the mixture is them laminated into the size of the original casting cake; and the cake containing the mixture is then cast on the light emitting chip using the casting machine and dies. The casting method though allowing control of consistent amount of he encapsulating material is found with the problem of having the encapsulating material stripped from the carrier particularly when the cake has higher containment of fluorescent powder, thinner, or smaller in volume.

### SUMMARY OF THE INVENTION

The primary purpose of he present invention is to provide an LED manufacturing process to correct problems found with the prior art. To achieve the purpose, the fluorescent material in smaller grains is mixed with a plastic material to become an encapsulating material to be jet printed onto the peripheral of the light emitting chip. Jet printing permits faster production and significantly upgraded production capacity while precise control over the amount of the encapsulating material by controlling the size of the nozzle and jet location to eliminate the strip off problem occurred in the casting method.

### BRIEF DESCRIPTION OF EH DRAWINGS

FIG. 1 is a schematic view showing a construction of an LED of the prior art.

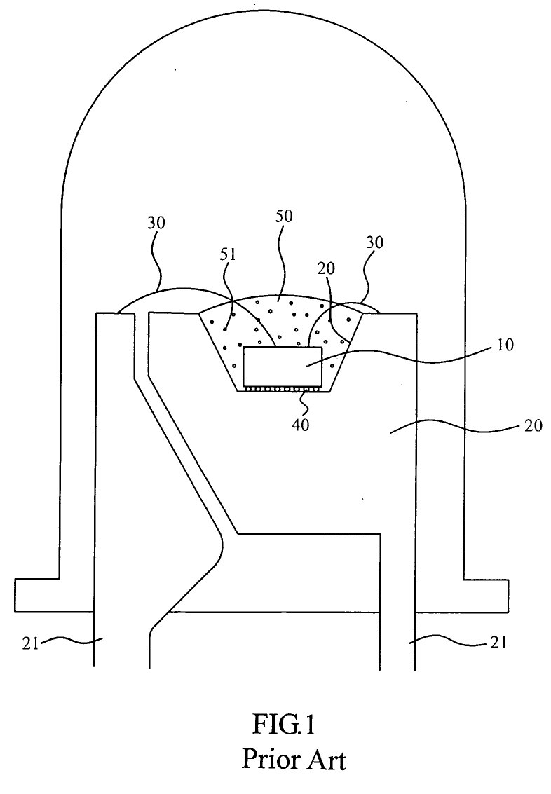

FIG. 2 is a manufacturing process flow chart of the present invention.

FIG. 3 is a schematic view showing a construction of a white LED of the present invention.

FIG. 4 is a schematic view showing a construction of jet printing of the encapsulating material from a nozzle in the present invention.

FIG. 5 is a perspective view of an LED produced using the manufacturing process of the present invention.

### DETAILED DESCRIPTION OF THE PREFERRED EMBODIMENTS

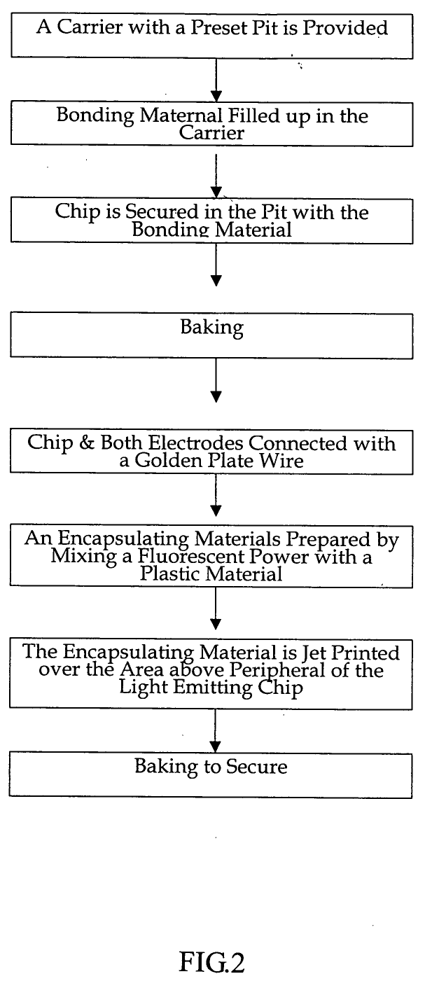

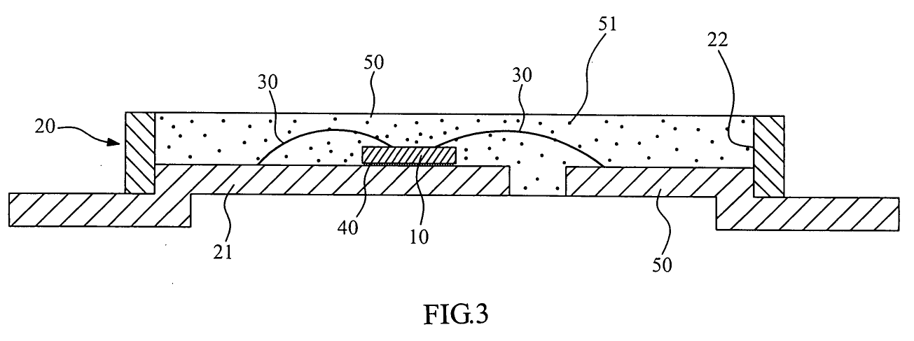

Referring to FIGS. 2 and 3, an LED manufacturing process of the present invention provides a carrier 20 containing a present pit 22; the carrier is applied with a bonding layer 40 to secure a light emitting chip 10 in the carrier 20; a goldenplated wire 30 connects the light emitting chip 10 and both electrodes 21; and the light emitting chip 10 is then applied with an encapsulating material 50 containing fluorescent powder 51. Accordingly, once the light emitting chip 10 is conducted, the fluorescent powder 51 in the encapsulating material 50 is excited to emit the light in expected color.

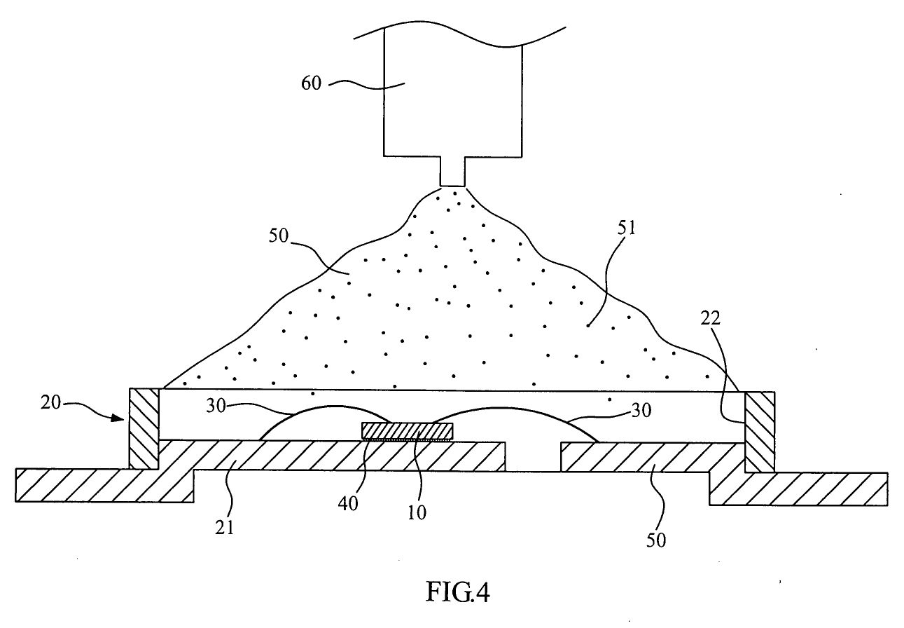

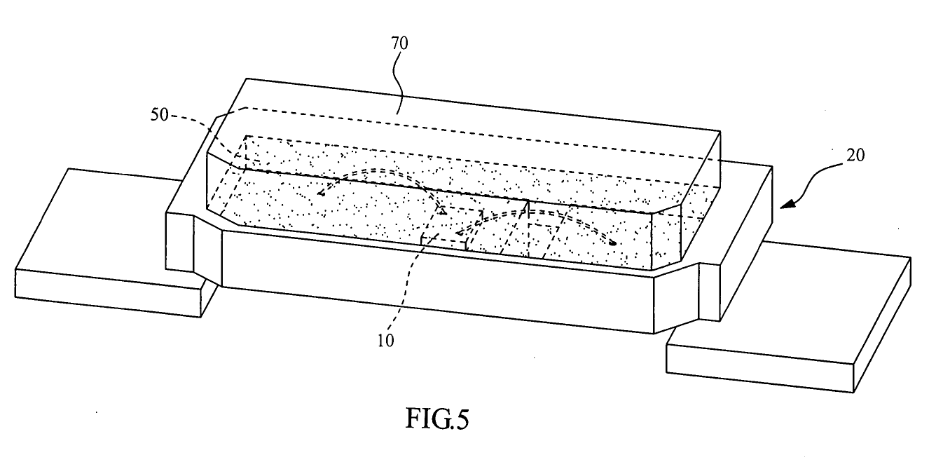

in a preferred embodiment of the present invention, the light emitting chip 10 is placed in the pit 22 and secured in the bonding layer 40 by baking. The golden plated wire 30 constitutes the connection between the light emitting chip 10 and both electrodes 21. The fluorescent material 51 in smaller grains is mixed with a plastic material to become the encapsulating material 50 and jet printed by means of a nozzle onto the area above the peripheral of the light emitting chip 10, as also illustrated in FIG. 4. Finally, the white LED is packed up with a transparent hood 70 to protect components inside as illustrated in FIG. 5.

The size of the nozzle 60 is adjusted depending on the size of he area to be encapsulated. The location of the nozzle 60 and the amount of the encapsulating material 50 are controlled by the location of the light emitting chip 10. In turn, the amount of the encapsulating material 51 can be controlled by the size and the location of the nozzle to eliminate the strip off problem between the encapsulating material and the carrier due to the stress found with the casting method of the prior art.

Depending on the light color desired the compositions of the light emitting chip and the fluorescent material are changed. For example, when a light color closer to white effects is expected, a blue light emitting chip is used and the blue light emitting chip is then encapsulated with an encapsulating material containing yellow fluorescent material. Similarly, an encapsulating material containing red and green fluorescent powders is applied to the blue light emitting chip, and when excited, both of the red and green fluorescent powders emit red and green lights to be incorporated into the blue light emitted form the blue light emitting chip for achieving RGB mixed light effects to produce a light color with high color development performance that is approaching white light color.

The prevent invention provides an improved LED manufacturing process,and the application for a patent is duly filed accordingly. However, it is to be noted that the preferred embodiments disclosed in the specification and the accompanying drawings are not limiting the present invention; and that any construction, installation, or characteristics that is same or similar to that of the present invention should fall within the scope of the purposes and claims of the present invention.

I claim:

1. An LED manufacturing process includes the following steps:
a. A carrier provided with a present pit is provided, and the carrier is filled up with a chip bonding material;
b. The chip is secured in the bonding material and baked in position;
c. The chip is electrically connected to two electrodes;
d. An encapsulating material comprised of a fluorescent powder and a plastic material is jet printing on the area above the peripheral of the chip; and
The encapsulating material is baked.

2. The LED manufacturing process of claim 1, wherein the encapsulating material is jet printed using a nozzle towards the area over the peripheral of the light emitting chip.

3. The LED manufacturing process of claim 1, wherein the encapsulating materials is comprised of a mixture of a fluorescent material in smaller grains and a plastic material.

4. The LED manufacturing process of claim 1, wherein a golden plated wire constitutes the connection between the blue light chip and both electrodes.

5. The LED manufacturing process of claim 1, wherein the entire LED is packed with a transparent hood.
